(19) United States
(12) Patent Application Publication
(10) Pub. No.: US 2011/0237087 A1
(43) Pub. Date: Sep. 29, 2011

(54) PATTERN INSPECTION METHOD AND SEMICONDUCTOR DEVICE MANUFACTURING METHOD

(76) Inventor: Ryoji YOSHIKAWA, Yokohama-shi (JP)

(21) Appl. No.: 13/051,654

(22) Filed: Mar. 18, 2011

(30) Foreign Application Priority Data
Mar. 24, 2010 (JP) 2010-068432

(51) Int. Cl. H01L 21/02; G06K 9/68; G06K 9/46

(52) U.S. Cl. 438/795; 382/218; 382/190; 257/E21.002

(57) ABSTRACT

According to one embodiment, there is provided a pattern inspection method including processing design data for an inspection pattern based on information dependent on an illumination condition of illumination used to inspect the inspection pattern, generating reference data for the inspection pattern from the processed design data, and comparing data for an actually formed inspection pattern with the reference data.

### CROSS-REFERENCE TO RELATED APPLICATIONS

This application is based upon and claims the benefit of priority from Japanese Patent Application No. 2010-068432, filed Mar. 24, 2010; the entire contents of which are incorporated herein by reference.

### FIELD

Embodiments described herein relate generally to a pattern inspection method and a semiconductor device manufacturing method.

### BACKGROUND

When a pattern inspection for a photomask is conducted, data (sensor data) for an image of an inspection pattern is compared with reference data which is obtained by expanding design data, and variances between these data are extracted as defects.

Meanwhile, as semiconductor devices are miniaturized, it is more difficult to obtain a proper image. Thus, there is a suggestion to set the shape and polarization state of illumination used for the imaging of the inspection pattern to a special state and thereby obtain a proper image (e.g., see Jpn. Pat. Appln. KOKAI Publication No. 2008-9339).

However, as semiconductor devices are more miniaturized, there may be a great error between the image data and the reference data depending on the shape and polarization state of the illumination. As a result, a problem arises; for example, a highly accurate pattern inspection Cannot be conducted.

### BRIEF DESCRIPTION OF THE DRAWINGS

FIG. 1 is a diagram schematically showing the configuration of a pattern inspection apparatus according to an embodiment;

FIG. 2A and FIG. 2B are diagrams showing the relation between a pattern dimension and optical image contrast when normal illumination is used;

FIG. 3A and FIG. 3B are diagrams showing the relation between a pattern dimension and optical image contrast when small σ illumination is used;

FIG. 4A and FIG. 4B are diagrams showing the relation between a pattern dimension and optical image contrast when annular illumination is used;

FIG. 5A, FIG. 5B, FIG. 5C, and FIG. 5D are views showing defect judgment according to a first comparative example of the embodiment;

FIG. 6A, FIG. 6B, FIG. 6C, and FIG. 6D are views showing defect judgment according to a second comparative example of the embodiment;

FIG. 7A, FIG. 7B, FIG. 7C, FIG. 7D, and FIG. 7E are views showing defect judgment according to the embodiment;

FIG. 8 is a flowchart schematically showing the outline of a pattern inspection method according to the embodiment;

FIG. 9 is a diagram schematically showing the outline of the entire surface of a lithography mask according to the embodiment; and

FIG. 10 is a flowchart showing the outline of a semiconductor device manufacturing method according to the embodiment.

### DETAILED DESCRIPTION

In general, according to one embodiment, there is provided a pattern inspection method comprising: processing design data for an inspection pattern based on information dependent on an illumination condition of illumination used to inspect the inspection pattern; generating reference data for the inspection pattern from the processed design data; and comparing data for an actually formed inspection pattern with the reference data.

Hereinafter, the embodiment will be described with reference to the drawings.

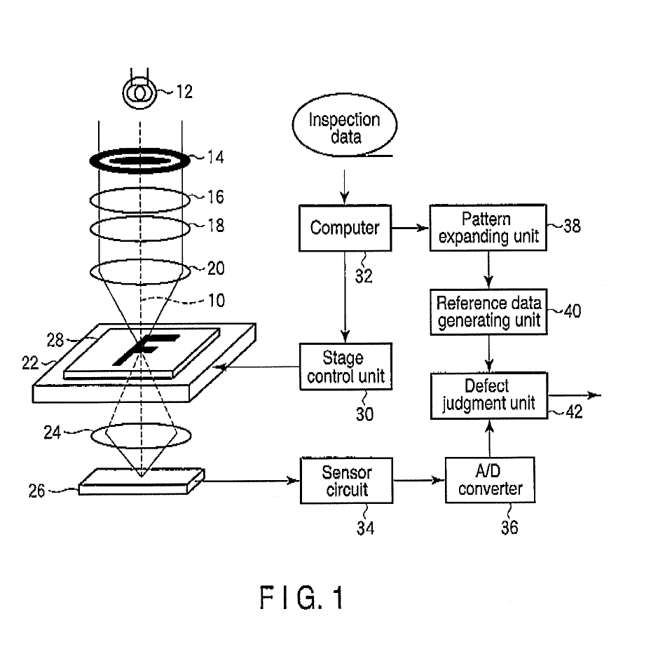

FIG. 1 is a diagram schematically showing the configuration of a pattern inspection apparatus according to the embodiment.

As shown in FIG. 1, a light source (e.g., argon laser) 12, a diaphragm 14, a ½ wave plate 16, a ¼ wave plate 18, a condensing lens 20, an XY stage 22, an objective lens 24 and an image sensor 26 are arranged along an optical axis 10. An imaging unit for imaging a pattern (inspection pattern) on a lithography mask (inspection substrate) 28 mounted on the XY stage 22 is constituted by the light source 12, the diaphragm 14, the ½ wave plate 16, the ¼ wave plate 18, the condensing lens 20, the objective lens 24 and the image sensor 26.

A state control unit 30 is connected to the XY stage 22, and the stage control unit 30 is controlled by a computer 32 so that the XY stage 22 can move in an X direction or Y direction. The lithography mask 28 can be moved to a desired position by moving the XY stage 22.

For example, a CCD sensor in which CCDs are one-dimensionally or two-dimensionally arranged can be used for the image sensor 26. Even if the light-receiving area of the image sensor 26 is small, the lithography mask 28 can be moved in the X direction or Y direction relative to the image sensor 26, such that the whole pattern formed on the lithography mask 28 can be imaged. The image of the pattern on the lithography mask 28 is formed on the image sensor 26 by an optical system comprising, for example, the condensing lens 20 and the objective lens 24 so that the image is enlarged, for example, several hundred times. Reflected light may be used instead of transmitted light depending on the characteristics of the lithography mask 28. Moreover, light in which transmitted light and reflected light are mixed may be used.

Data (sensor data) for an optical image corresponding to the pattern image of the whole lithography mask 28 obtained from the image sensor 26 is output from a sensor circuit 34. The pixel size of the sensor data is, for example, 100 nm×100 nm.

An A/D converter 36 A/D-converts the sensor data (sensor signal) from the sensor circuit 34.

A pattern expanding unit 38 expands inspection data for a mask pattern input via the computer 32 to multiple-valued tone data having resolution substantially equal to that of the sensor data. When the sensor data is binary, the pattern expanding unit 38 expands the inspection data to binary tone data. As described later, it has heretofore been the case that the inspection data corresponds to design data for the inspection pattern, and corresponds to writing data for the mask pattern subjected to processing such as an optical proximity correction (OPC). In the present embodiment, the inspection data is obtained by processing the design data for the inspection pattern based on information dependent on the illumination condition of illumination used to inspect the inspection pattern. That is, the inspection data is obtained by processing the writing data for the mask pattern subjected to processing such as the OPC. In addition, the inspection data is generated by, for example, CAD.

A reference data generating unit 40, for example, filters the data from the pattern expanding unit 38 to generate reference data for comparison with the sensor data obtained by imaging the lithography mask. Specifically, the reference data generating unit 40 generates the reference data in consideration of a shape change caused by, for example, an etching process of a pattern formed on the lithography mask. The pixel size of the reference data is the same (e.g., 100 nm×100 nm) as the pixel size of the sensor data.

Defect judgment unit 42 compares the sensor data from the AID converter 36 with the reference data from the reference data generating unit 40 to generate defect data. Specifically, the defect judgment unit 42 generates a difference image between the sensor data and the reference data, and judges the presence of any defect of the pattern on the basis of the difference image. That is, the defect judgment unit 42 compares the data (sensor data) for the inspection pattern actually formed on the lithography mask with the reference data to judge the presence of any defect.

Here, the illumination to illuminate the lithography mask 28 which is an inspection target is described.

In the example shown in FIG. 1, the ½ wave plate (λ/2 plate) 16 and the ¼ wave plate (λ/4 plate) 18 are arranged above the lithography mask 28. Thus, the ½ wave plate 16 and the ¼ wave plate 18 are arranged so that the polarization state of the illumination light can be controlled. The angles of the ½ wave plate 16 and the ¼ wave plate 18 are properly set so that linearly polarized light generated from the light source 12 is converted to circularly polarized light or to linearly polarized light having a given angle. The circularly polarized light or linearly polarized light obtained by such conversion is applied to the lithography mask 28.

Here, the ½ wave plate (λ/2 plate) is an optical component which can rotate to change the polarization direction of the linearly polarized light. The ¼ wave plate (λ/4 plate) is an optical component which can change the linearly polarized light to circularly polarized light or elliptically polarized light. The directions of the two wave plates can be adjusted to improve optical resolution. That is, when the pattern of the lithography mask has directionality, the polarization direction is aligned with the direction of the pattern by use of the linearly polarized light to improve optical resolution. Thus, an inspection region that requires a high inspection sensitivity can be inspected with the enhanced resolution. When the direction of the pattern is not fixed, an inspection can be conducted by use of the circularly polarized light to ensure inspection sensitivity independently of the direction of the pattern.

The aperture of the diaphragm 14 provided at a position conjugate with the pupil plane of the objective lens 24 may be shaped to transmit a particular part. Thus, the angle of the illumination light can be set so that N th diffraction light of the pattern of a subject is focused on the objective lens. When a diaphragm having an annular aperture as a particular part is used, more diffraction light of the pattern of the subject can be taken in, and background light that does not contribute to contrast can be blocked, so that optical resolution for a periodic pattern can be enhanced. Moreover, diffraction light of a line-and-space pattern (L/S pattern) is focused on the objective lens by an annular diaphragm to enhance optical resolution for the L/S pattern, and an aperture is provided in the center to permit diffraction light other than the diffraction light of the periodic pattern to be also focused. As a result, contrast of patterns other than the L/S pattern can also be secured.

Now, the optical image contrast characteristics of the sensor data and the reference data when the illumination shape is changed are described.

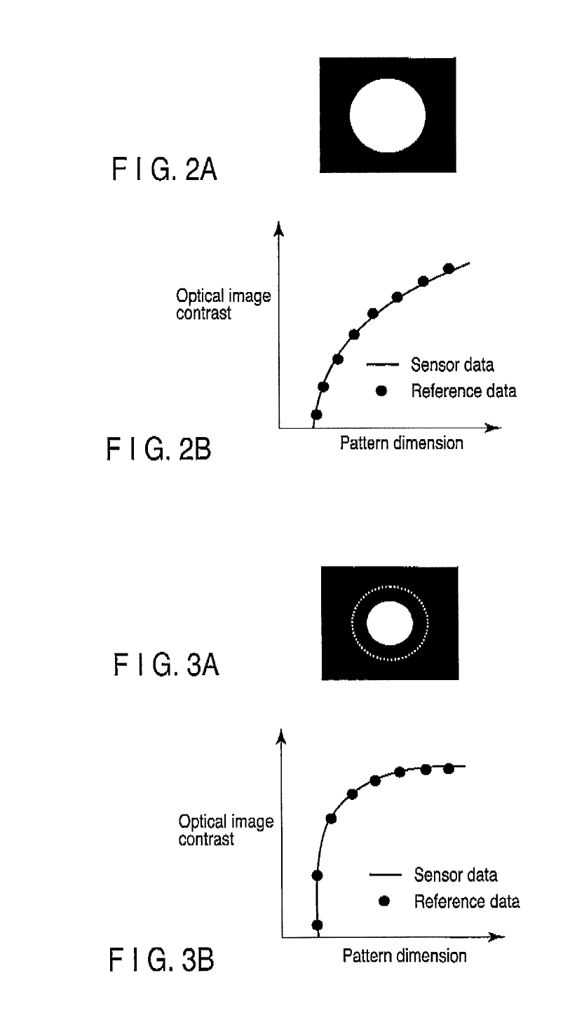

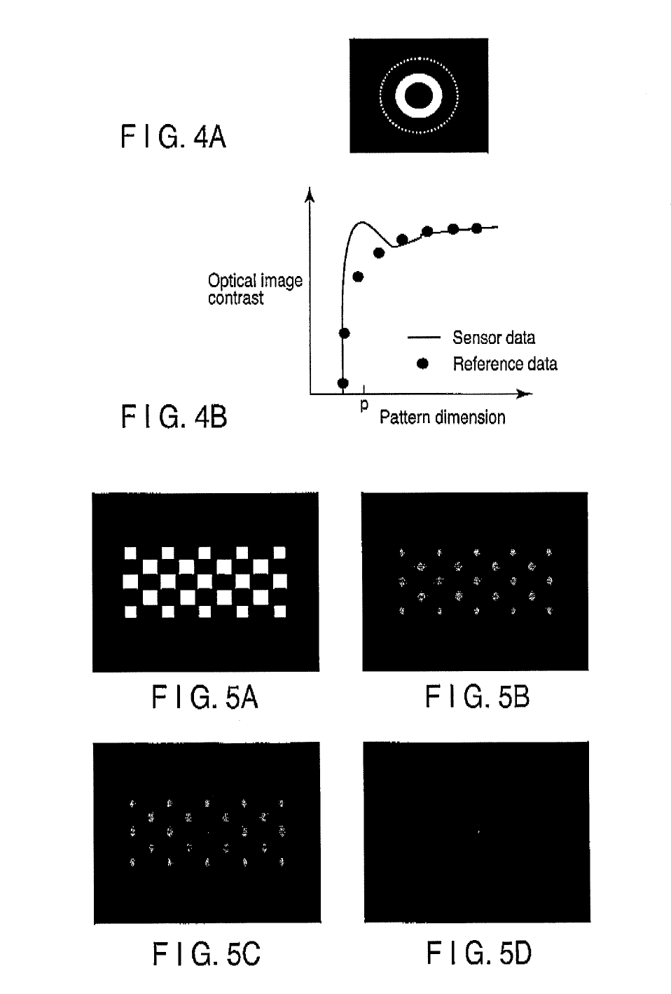

FIG. 2A and FIG. 2B show the case of normal illumination (σ=1.0). FIG. 3A and FIG. 3B show the case of small σ illumination (σ=0.6). FIG. 4A and FIG. 4B show the case of annular illumination. FIG. 2A, FIG. 3A, and FIG. 4A are views showing the illumination shapes. FIG. 2B, FIG. 3B, and FIG. 4B are graphs showing the relation between a pattern dimension (the dimension of an L/S pattern) and optical image contrast.

In FIG. 2A and FIG. 2B and in FIG. 3A and FIG. 3B, the characteristics of the sensor data obtained by imaging the pattern closely agree with the characteristics of the reference data obtained by expanding the design data. On the contrary, in FIG. 4A and FIG. 4B, there are parts where the characteristics of the sensor data disagree with the characteristics of the reference data. The radius of the aperture of the diaphragm is calculated to enhance the optical resolution, that is, contrast when an L/S pattern having a dimension p is imaged. Therefore, optical image contrast in the vicinity of the pattern dimension p of the sensor data is increased. On the contrary, the reference data cannot represent the increase of the optical image contrast in the vicinity of the pattern dimension p. As a result, the difference between the characteristics of the sensor data and the characteristics of the reference data is great in the vicinity of the pattern dimension p. Therefore, when a pattern inspection is conducted by using, for example, the annular illumination in FIG. 4A and FIG. 4B, resolution can be enhanced for a particular pattern, but on the other hand, there may be a great error between the characteristics of the sensor data and the characteristics of the reference data.

Now, defect judgment is described.

FIG. 5A, FIG. 5B, FIG. 5C, and FIG. 5D are views showing defect judgment according to a first comparative example of the present embodiment. In the example shown in FIG. 5A, FIG. 5B, FIG. 5C, and FIG. 5D, a pattern inspection is conducted by using the normal illumination.

FIG. 5A shows a pattern of the inspection data. In the present comparative example, the inspection data is the same as the design data, that is, writing data for the inspection pattern. FIG. 5C shows a pattern of the sensor data imaged by the image sensor. Contact hole patterns which are substantially rectangular on the lithography mask are circular in the pattern of the sensor data owing to the optical characteristics. Moreover, since the contact hole patterns in the center of FIG. 5C are defective, the intensity of light is reduced. FIG. 5B shows a pattern of the reference data. This reference data is generated by the reference data generating unit after the inspection data is converted into a multiple-valued form in the pattern expanding unit. A shape change caused by, for example, optical characteristics and the characteristics of an etching process is reflected in this reference data. In the present comparative example, the sensor data closely agrees with the reference data. FIG. 5D shows the difference between the reference data of FIG. 5B and the sensor data of FIG. 5C. There is a light intensity difference in a defective portion.

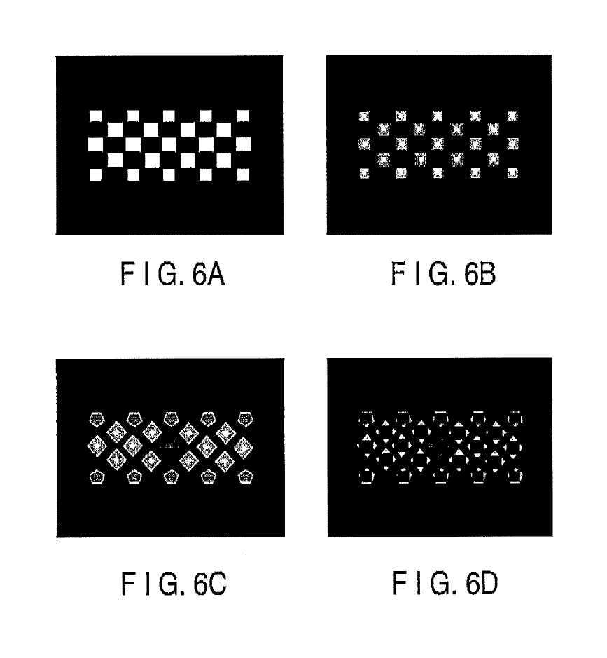

FIG. 6A, FIG. 6B, FIG. 6C, and FIG. 6D are views showing defect judgment according to a second comparative example of the present embodiment. In the example shown in FIG. 6A, FIG. 6B, FIG. 6C, and FIG. 6D, a pattern inspection is conducted by using the annular illumination. As in the case of FIG. 5A, FIG. 5B, FIG. 5C, and FIG. 5D, FIG. 6A shows a pattern of the inspection data (the design data, i.e., writing data for the inspection pattern), FIG. 6B shows a pattern of the reference data, FIG. 6C shows a pattern of the sensor data, and FIG. 6D shows the difference between the reference data and the sensor data.

When special illumination such as the annular illumination is used to enhance the optical resolution, the contrast of the sensor data is improved, but the shape of the pattern of the sensor data may be greatly changed. As shown in FIG. 6C, the contrast of the sensor data is increased (light intensity is increased), but the shapes of contact hole patterns are diamond-shaped. However, the diamond shapes are not represented in the reference data of FIG. 6B. Thus, as shown in FIG. 6D, difference images (difference signals) between the reference data and the sensor data are generated in portions other than the defective portions, and defects cannot be extracted with accuracy.

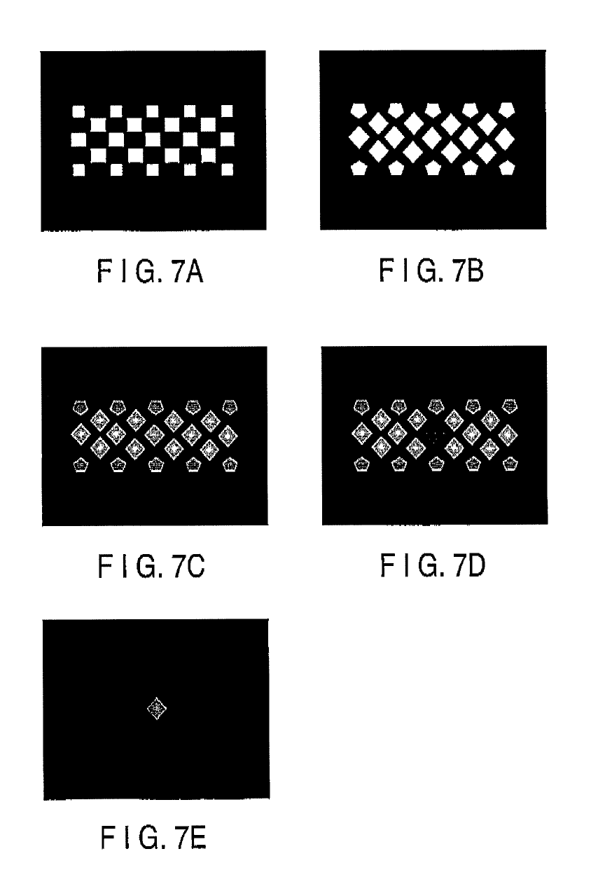

FIG. 7A, FIG. 7B, FIG. 7C, FIG. 7D, and FIG. 7E are views showing defect judgment according to the embodiment, In this case, a pattern inspection is conducted by using the annular illumination. FIG. 7A shows a pattern of the design data (writing data) for the inspection pattern. FIG. 7B shows a pattern of the inspection data. FIG. 7C shows a pattern of the reference data. FIG. 7D shows a pattern of the sensor data. FIG. 7E shows the difference between the reference data and the sensor data. As shown in FIG. 7A, FIG. 78, FIG. 70, FIG. 7D, and FIG. 7E, in the present embodiment, the design data (writing data) for the inspection pattern is not the same as the inspection data, in contrast with the first comparative example and second comparative example described above.

The inspection data in FIG. 7B is described below. The inspection data in FIG. 7B is obtained by processing the design data for the inspection pattern in FIG. 7A based on information dependent on an illumination condition of illumination used to inspect the inspection pattern. The illumination condition includes at least one of the illumination shape of the illumination and the polarization state of the illumination. Specifically, a predictive shape of the inspection pattern is simulated by use of the illumination condition, and the design data for the inspection pattern is processed based on the obtained simulation information, thereby obtaining the inspection data in FIG. 7B. From the design data (inspection data) for the inspection pattern thus processed, the reference data in FIG. 7C is then generated. That is, the inspection data is generated so that the data (sensor data) for the inspection pattern actually formed on the lithography mask may agree with the reference data as much as possible.

In the present embodiment, the reference data is generated as described above, so that the reference data shown in FIG. 7C closely agrees with the sensor data shown in FIG. 7D. Thus, defective portions alone are extracted as difference images in the difference between the reference data and the sensor data shown in FIG. 7E. That is, the design data is processed in consideration of the illumination condition such as the illumination shape and the polarization state to generate inspection data, and the reference data is generated from this inspection data, such that the precise reference data can be generated even by use of an existing reference data generating unit. Moreover, the difference image benefits from the enhanced contrast of the pattern and can have much higher defect signals than the difference images provided by the normal illumination.

In addition, the above-mentioned illumination condition may further include a wavelength of the illumination and a numerical aperture of the illumination used for the inspection, in addition to the illumination shape and polarization state of the illumination used for the inspection. Moreover, when the inspection data is generated, the design data for the inspection pattern may be processed based on information dependent on the optical characteristics of the inspection pattern in addition to the information dependent on the illumination condition of the illumination used to inspect the inspection pattern. As a result, a more precise inspection pattern and reference data can be generated. The optical characteristics of the inspection pattern include a phase difference of the inspection pattern (e.g., a phase difference between transmitted light in a transmission portion of the lithography mask and transmitted light in a halftone portion), and the transmittance of the inspection pattern (e.g., the transmittance in the transmission portion, halftone portion, and light blocking portion of the lithography mask).

Furthermore, the illumination condition used in the method described above is preferably the same as an illumination condition for transferring, to a semiconductor substrate (semiconductor wafer), the pattern on the lithography mask inspected by the method described above. As a result, a precise pattern inspection that takes into consideration the characteristics of the transfer of the pattern to the semiconductor substrate (semiconductor wafer) can be conducted.

Still further, according to the method described above, the inspection data is generated based on the information obtained by simulating the predictive shape of the inspection pattern. However, the inspection data may be generated based on information obtained by predicting the predictive shape of the inspection pattern on the basis of a previously obtained experimental result. Specifically, predictive shapes of various patterns are experimentally obtained in advance for various illumination conditions and set in a table. Thus, a predictive shape of the inspection pattern under the illumination condition used in an actual inspection is predicted by reference to the table.

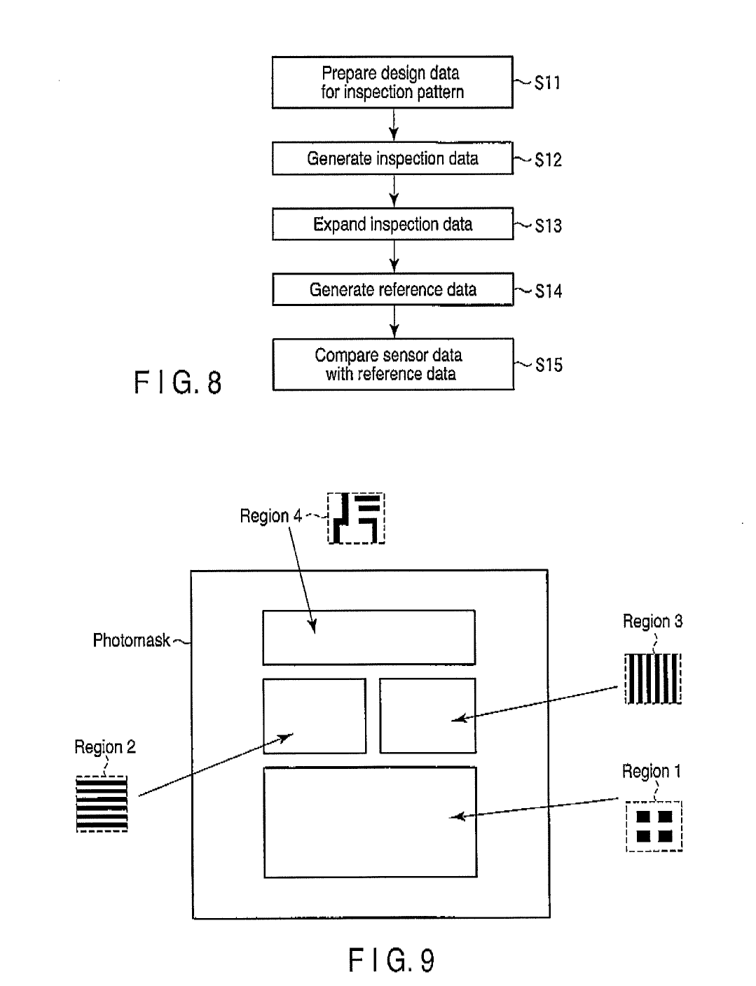

FIG. 8 is a flowchart schematically showing the outline of a pattern inspection method which is carried out on the basis of the method according to the present embodiment. The pattern inspection method according to the present embodiment is described below with reference to FIG. 1 and FIG. 8.

First, design data (writing data) for an inspection pattern formed on a lithography mask is prepared (S11). Further, inspection data is generated by processing the design data for the inspection pattern based on information dependent on the illumination condition of illumination used to inspect the inspection pattern (S12). The generated inspection data is sent to the pattern expanding unit 38 via the computer 32, and the pattern expanding unit 38 expands the inspection data to tone data (S13). The reference data generating unit 40, for example, filters the data output from the pattern expanding unit 38 to generate reference data (S14). The defect judgment unit 42 compares sensor data from the A/D converter 36 with the reference data from the reference data generating unit 40 to generate defect data (S15). That is, the defect judgment unit 42 generates a difference image between the sensor data and the reference data, and judges the presence of any defect of the pattern on the basis of the difference image.

As described above, according to the present embodiment, the inspection data is generated by processing the design data for the inspection pattern based on the information dependent on the illumination condition of the illumination used to inspect the inspection pattern. The reference data for the inspection pattern is generated from the inspection data. Thus, even when an inspection is conducted by using modified illumination such as the annular illumination, the degree of agreement between the data (sensor data) for the inspection pattern actually formed on the lithography mask and the reference data can be increased. Consequently, defects present in the inspection pattern can be precisely extracted by comparing the sensor data with the reference data, and the inspection pattern can be precisely inspected.

Now, an inspection of the entire surface of the lithography mask by the above pattern inspection method is described. FIG. 9 is a diagram schematically showing the outline of the entire surface of the lithography mask.

In the example shown in FIG. 9, four regions (a region 1 to a region 4) are included in the lithography mask. A contact pattern is disposed in the region 1. A lateral line-and-space pattern (L/S pattern) is disposed in the region 2. A longitudinal line-and-space pattern (L/S pattern) is disposed in the region 3. A logic pattern is disposed in the region 4.

For example, when a high inspection sensitivity is required for the line-and-space patterns, the entire surface of the lithography mask is inspected by using the annular illumination to enhance the resolution in the region 2 and the region 3. For the region 2 and the region 3, inspection data generated by processing design data based on the above-described method is used. For the region 1 and the region 4, design data is used as inspection data without processing, as in the case of conventional methods. Further, reference data is generated from the inspection data, and data (sensor data) for the pattern actually formed on the lithography mask is compared with the reference data.

If a pattern inspection is conducted by the above-described method, the entire surface of the lithography mask can be efficiently inspected without changing the illumination region by region.

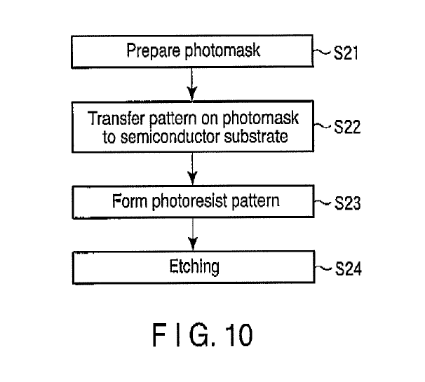

FIG. 10 is a flowchart showing the outline of a semiconductor device manufacturing method that uses the lithography mask inspected by the above-described pattern inspection method.

First, a lithography mask inspected by the above-described pattern inspection method is prepared (S21). A pattern on the lithography mask is then transferred to a photoresist on a semiconductor substrate (semiconductor wafer) (S22). The photoresist is then developed to form a photoresist pattern (S23). Further, the photoresist pattern is used as a mask to carry out etching, thereby forming a desired pattern on the semiconductor substrate.

If a semiconductor device is manufactured by the lithography mask inspected by the above-described pattern inspection method, the semiconductor device in which defects are restrained can be effectively produced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern inspection method comprising:
processing design data for an inspection pattern based on information dependent on an illumination condition of illumination used to inspect the inspection pattern;
generating reference data for the inspection pattern from the processed design data; and
comparing data for an actually formed inspection pattern with the reference data.

2. The method according to claim 1, wherein the illumination condition includes at least one of an illumination shape of the illumination and a polarization state of the illumination.

3. The method according to claim 2, wherein
the illumination condition further includes at least one of a wavelength of the illumination and a numerical aperture of the illumination.

4. The method according to claim 2, wherein the illumination shape includes modified illumination.

5. The method according to claim 4, wherein the modified illumination includes annular illumination.

6. The method according to claim 1, wherein
the information is further dependent on optical characteristics of the inspection pattern.

7. The method according to claim 6, wherein
the optical characteristics include at least one of a phase difference and transmittance of the inspection pattern.

8. The method according to claim 1, wherein
the information is obtained by simulating a predictive shape of the inspection pattern based on the illumination condition.

9. The method according to claim 1, wherein
the information is obtained by predicting a predictive shape of the inspection pattern based on a previously obtained experimental result.

10. The method according to claim 1, wherein
the illumination condition is the same as an illumination condition for transferring a pattern on a lithography mask inspected by the pattern inspection method.

11. The method according to claim 1, wherein
the inspection pattern includes a line-and-space pattern.

12. The method according to claim 1, wherein
the data for the actually formed inspection pattern is obtained by imaging the actually formed inspection pattern.

13. The method according to claim 1, wherein
comparing the data for the actually formed inspection pattern with the reference data includes generating a difference image between an image based on the data for the actually formed inspection pattern and an image based on the reference data.

14. A semiconductor device manufacturing method comprising:
preparing a lithography mask inspected by the pattern inspection method according to claim 1; and
transferring, onto a semiconductor substrate, a pattern on the lithography mask.
